(19) United States
(12) Patent Application Publication
(10) Pub. No.: US 2015/0340254 A1
(43) Pub. Date: Nov. 26, 2015

(54) WAFER HOLDER AND DEPOSITION APPARATUS

(71) Applicant: Kabushiki Kaisha Toshiba, Minato-ku (JP)

(72) Inventors: Takuya MATSUDA, Kamakura (JP); Takahiro TERADA, Yokohama (JP); Tadashi SHIMMURA, Yokohama (JP); Hiroshi MATSUBA, Yokohama (JP); Hiroaki KOBAYASHI, Yokohama (JP); Noriyuki MORIYA, Yokohama (JP)

(73) Assignee: Kabushiki Kaisha Toshiba, Minato-ku (JP)

(21) Appl. No.: 14/714,534

(22) Filed: May 18, 2015

(30) Foreign Application Priority Data
May 23, 2014 (JP) 2014-107557

(51) Int. Cl. H01L 21/67; C23C 16/458; C23C 16/455; H01L 21/673; C23C 16/46

(52) U.S. Cl. CPC H01L 21/67103; H01L 21/67326; C23C 16/46; C23C 16/455; C23C 16/458

(57) ABSTRACT

According to an embodiment, a wafer holder includes a heat receiving portion, a heating portion, and a contact making portion. The heat receiving portion receives heat from a heat source. The heating portion heats a wafer using the heat received by the heat receiving portion. The contact making portion makes contact with an outer edge of the wafer. A heat-transfer suppressing portion is provided at least either for the contact making portion, or in between the heat receiving portion and the contact making portion, or in between the heating portion and the contact making portion.

### CROSS-REFERENCE TO RELATED APPLICATION(S)

This application is based upon and claims the benefit of priority from Japanese Patent Application No. 2014-107557, filed on May 23, 2014; the entire contents of which are incorporated herein by reference.

### FIELD

Embodiments described herein relate generally to a wafer holder and a deposition apparatus.

### BACKGROUND

Typically, a deposition apparatus is known in which, while a wafer holder that is holding a wafer is rotated, the wafer is heated via the wafer holder and a gas is supplied onto the wafer so that a film gets formed on the wafer by means of vapor deposition.

In such a deposition apparatus, if the temperature distribution of the wafer varies widely, there are times when the thickness of the film exhibits variability. For that reason, it would be significant if a wafer holder and a deposition apparatus can be achieved with a new configuration that enables controlling variability in the temperature distribution of the wafer.

### BRIEF DESCRIPTION OF THE DRAWINGS

FIG. 1 is an exemplary perspective view of a cross-sectional surface of a deposition apparatus according to a first embodiment;

FIG. 2 is an exemplary cross-sectional view of the deposition apparatus according to the first embodiment;

FIG. 3 is an exemplary planar view of a wafer holder according to the first embodiment;

FIG. 4 is an exemplary planar view of some portion of the wafer holder according to the first embodiment;

FIG. 5 is an exemplary cross-sectional view of some portion of the wafer holder and some portion of a wafer according to the first embodiment;

FIG. 6 is an exemplary cross-sectional view of some portion of the wafer holder according to the first embodiment;

FIG. 7 is an exemplary enlarged view that schematically illustrates a VII portion illustrated in FIG. 6;

FIG. 8 is an exemplary explanatory diagram for explaining the temperature distribution in the wafer holder according to the first embodiment;

FIG. 9 is an exemplary explanatory diagram for explaining the temperature distribution in a comparison example of the wafer holder according to the first embodiment;

FIG. 10 is an exemplary graph illustrating the correlation of gaps between two materials of the wafer holder and the temperature according to the first embodiment;

FIG. 11 is an exemplary cross-sectional view of some portion of a wafer holder and some portion of a wafer according to a first modification example of the first embodiment;

FIG. 12 is an exemplary cross-sectional view of some portion of the wafer holder according to the first modification example of the first embodiment;

FIG. 13 is an exemplary cross-sectional view of some portion of a wafer holder according to a second modification example of the first embodiment;

FIG. 14 is an exemplary cross-sectional view of some portion of a wafer holder and some portion of a wafer according to a second embodiment;

FIG. 15 is an exemplary cross-sectional view of a heat-transfer suppressing portion according to a third embodiment;

FIG. 16 is an exemplary enlarged view of an XVI portion illustrated in FIG. 15;

FIG. 17 is an exemplary cross-sectional view of some portion of a wafer holder and some portion of a wafer according to a fourth embodiment; and

FIG. 18 is an exemplary planar view of a wafer holder according to another embodiment.

### DETAILED DESCRIPTION

According to an embodiment, a wafer holder includes a heat receiving portion, a heating portion, and a contact making portion. The heat receiving portion receives heat from a heat source. The heating portion heats a wafer using the heat received by the heat receiving portion. The contact making portion makes contact with an outer edge of the wafer. A heat-transfer suppressing portion is provided at least either for the contact making portion, or in between the heat receiving portion and the contact making portion, or in between the heating portion and the contact making portion.

Exemplary embodiments and modification examples are described below in detail with reference to the accompanying drawings. In the embodiments and the modification examples described below, some identical constituent elements are included. Hence, in the following explanation, the identical constituent elements are referred to by the same reference numerals, and the redundant explanation is omitted.

### First Embodiment

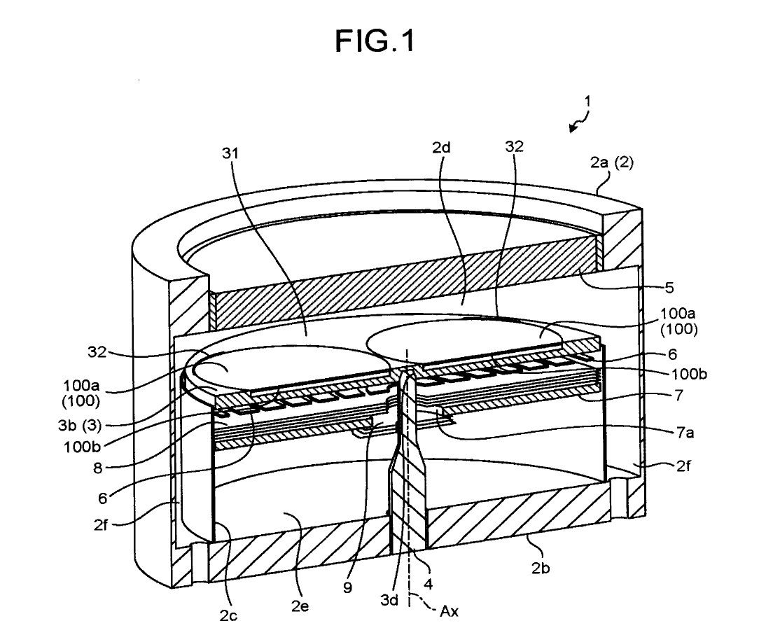

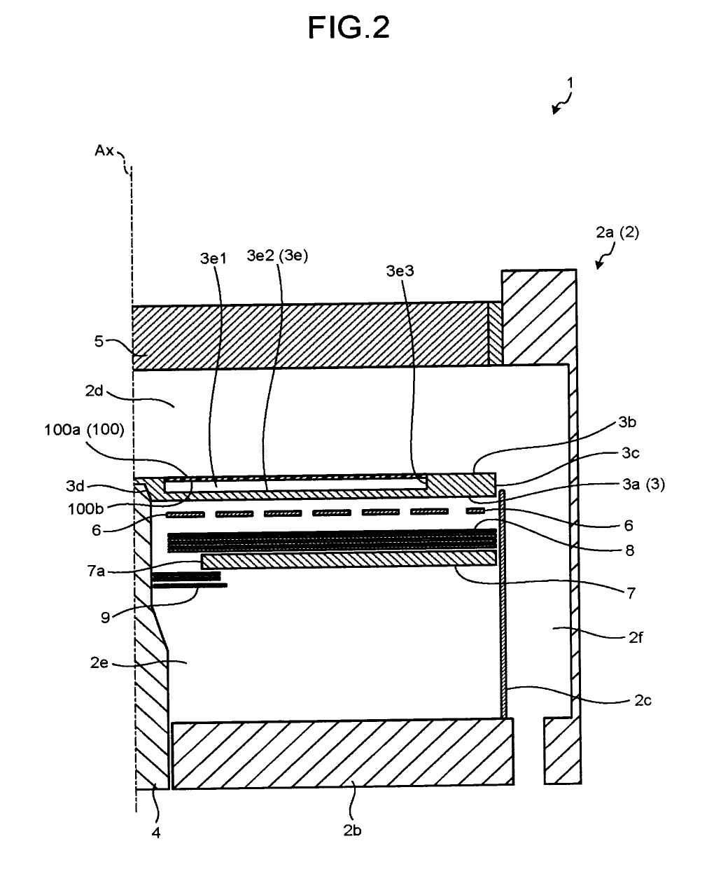

In a deposition apparatus 1 (a coating apparatus) illustrated in FIG. 1 according to a first embodiment, while wafers 100 are rotated around a rotation center Ax (a rotation center axis, see FIG. 2), a gas is supplied onto a face 100a of each wafer 100 so that a film is formed on that wafer 100 by means of vapor deposition. Herein, the deposition apparatus 1 is, for example, a chemical vapor deposition (CVD) apparatus or a metal organic chemical vapor deposition (MOCVD) apparatus. In the first embodiment, the rotation center Ax is positioned along, for example, the vertical direction (perpendicular direction). Moreover, each wafer 100 is formed in a disc shape, and has the circular face 100a and a circular face 100b that is on the opposite side of the face 100a.

As illustrated in FIGS. 1 and 2, the deposition apparatus 1 includes a container 2, a wafer holder 3 for holding the wafers 100, a shaft 4 for rotating the wafer holder 3, a gas supplying unit 5 for supplying gas into the container 2, a heater 6 for heating the wafers 100 via the wafer holder 3, and a cooling unit V.

The container 2 has a tubular portion 2a (a wall portion) and a bottom wail portion 2b (a wall portion). The tubular portion 2a is formed as a cylindrical portion around the rotation center Ax. At the bottom end of the tubular portion 2a is formed the bottom wall portion 2b, and an opening at the upper end of the tubular portion 2a is covered by the gas supplying unit 5. The bottom wall portion 2b is formed to have a substantially disc-like shape.

The container 2 also includes a tubular portion 2c that is positioned on the inside of the tubular portion 2a and that is formed to have a cylindrical shape around the rotation center Ax. Moreover, the tubular portion 2c extends in the upward direction from the bottom wall portion 2b. The upper end of the tubular portion 2c is positioned on the lower side than the upper end of the tubular portion 2a. The opening at the lower end of the tubular portion 2c is closed by the bottom wall portion 2b. Moreover, the wafer holder 3 is positioned to cover the opening at the upper end of the tubular portion 2c.

The container 2 includes two chambers 2d and 2e. The chamber 2d is surrounded by the gas supplying unit 5, the wafer holder 3, and some portion (the upper portion) of the tubular portion 2c. The chamber 2e is surrounded by the wafer holder 3, the bottom wall portion 2b, and the tubular portion 2c. Moreover, the container 2 includes an exhaust passage 2f, which passes in between the tubular portion 2a and the tubular portion 2c. The upper end (the inlet) of the exhaust passage 2f opens inside the chamber 2d, and the lower end (the vent) of the exhaust passage 2f opens on the outside of the bottom wall portion 2b.

The shaft 4 runs through the bottom wall portion 2b. Moreover, the shaft 4 is rotatable with respect to the bottom wall portion 2b (the container 2). Furthermore, the shaft 4 is driven by a motor (a driving source) and rotates around the rotation center Ax. The upper end of the shaft 4 has the wafer holder 3 joined (fixed) thereto. When the shaft 4 is rotary-driven by the motor (not illustrated), the wafer holder 3 rotates as a result.

The gas supplying unit 5 is positioned on the upper side of the wafer holder 3. In the gas supplying unit 5, a plurality of nozzles (not illustrated) is formed that opens inside the chamber 2d. The gas supplying unit 5 sprays (supplies) a gas (a source gas) inside the chamber 2d through the nozzles. The gas serves as the raw material for forming a film on the wafers 100.

The heater 6 (a heat source) is positioned inside the chamber 2e. Moreover, the heater 6 is positioned on the lower side of the wafer holder 3 and is facing the wafer holder 3. As an example, the heater 6 is configured in a spiral manner around the shaft 4 (the rotation center Ax).

The cooling unit 7 is positioned inside the chamber 2e and has a flat annular appearance. In the central part of the cooling unit 7, an opening 7a (a through hole) is formed through which the shaft 4 is inserted. The cooling unit 7 is of a liquid-cooled type including an internal passage (not illustrated) through which a cooling liquid flows. The cooling unit 7 cools the neighborhood thereof in such a way that the area (space) on the lower side of the cooling unit 7 in the chamber 2e is maintained at a substantially constant temperature.

Meanwhile, a reflector 8 (a heat insulation unit) is disposed in between the cooling unit 7 and the heater 6. The reflector 8 is flat and has an annular appearance around the shaft 4. Moreover, a reflector 9 is disposed on the lower side of the cooling unit 7. The reflector 9 covers the opening 7a of the cooling unit 7 from the lower side. The reflector 9 is flat and has an annular appearance around the shaft 4.

As illustrated in FIGS. 1 to 3, the wafer holder 3 is configured to have a substantially disc-like shape. In the planar view, the wafer holder 3 has a circular appearance centered on the rotation center Ax. The wafer holder 3 has a face 3a (the lower surface), a face 3b (the top surface, the upper surface), and a lateral face 3c (a side surface, a peripheral surface). The face 3a is positioned on the upper side of the heater 6 and is facing the heater 6 from some distance. Moreover, the face 3a has a circular shape. The face 3b lies on the opposite side of the face 3a, and has a circular shape. Moreover, the face 3b is positioned on the lower side of the gas supplying unit 5 and is facing the gas supplying unit 5 from some distance. The lateral face 3c is formed from the face 3a to the face 3b. Moreover, the lateral face 3c is a cylindrical surface around the rotation center Ax.

In the central part of the face 3a, a joining portion 3d is disposed and joined (fixed) to the upper end of the shaft 4.

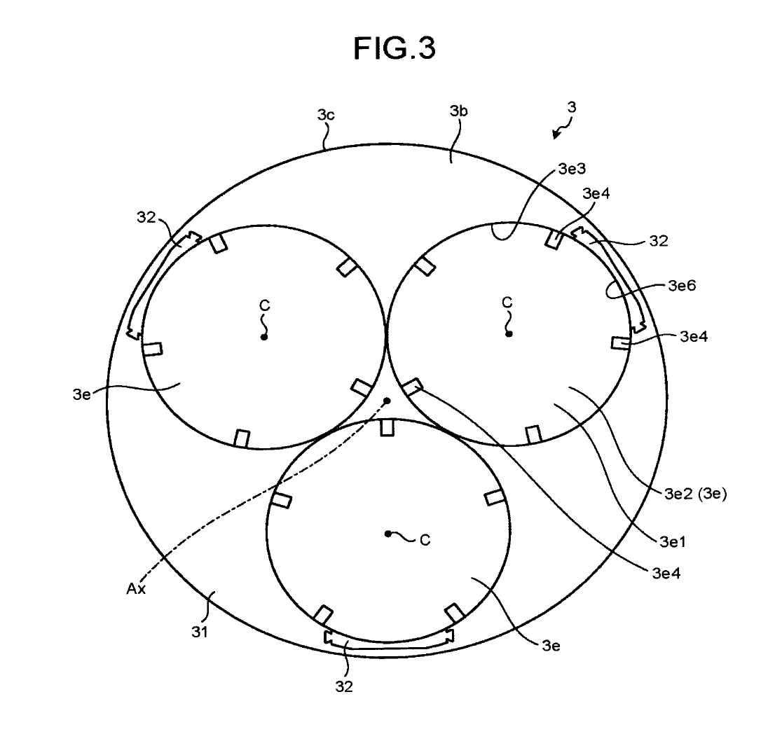

Moreover, on the face 3b, a plurality of housing units 3e is disposed along the circumferential direction of the rotation center Ax and is spaced apart from each other. With reference to FIG. 3, as an example, three housing units 3e are disposed. Each housing unit 3e has a depression 3e1 (an opening) formed toward the face 3a from the face 3b. The depression 3e1 is formed in a vertically-thin cylindrical shape with an opening in the upward direction. Each housing unit 3e (each depression 3e1) houses a single wafer 100.

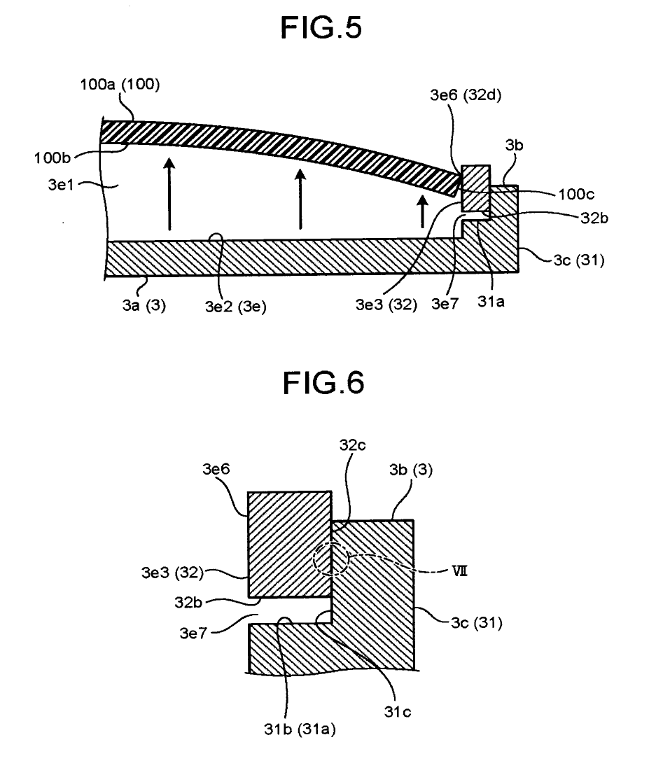

Each housing unit 3e has a bottom face 3e2 (a face) and has a face 3e3 that extends in the upward direction from the bottom face 3e2. Herein, the bottom face 3e2 is formed in a circular shape. Moreover, the bottom face 3e2 has convex supporting members 3e4 (claws) disposed thereon. The supporting members 3e4 are disposed on the outer edge of the bottom face 3e2 and are spaced apart from each other along the circumferential direction of the corresponding housing unit 3e. The wafer 100 is mounted on the supporting members 3e4. Thus, the supporting members 3e4 support the outer edge of the face 100b of the wafer 100. As illustrated in FIG. 5, the wafer 100 that is supported by the supporting members 3e4 is separated from the bottom face 3e2. That is, the bottom face 3e2 is positioned separated from the wafer 100 in the thickness direction of the wafer 100.

As illustrated in FIG. 2, the face 3e3 extends in the upward direction from the outer edge of the bottom face 3e2. Herein, the face 3e3 is formed in a substantially cylindrical shape. Moreover, the face 3e3 has a greater diameter than the diameter of the wafer 100. Therefore, a gap (space) is formed in the entire region or in some part of the region between the face 3e3 and an outer edge 100c of the wafer 100 that is housed in the housing unit 3e. When the wafer holder 3 rotates, a centrifugal force toward the outside of the radial direction of the rotation center Ax gets applied to the wafer 100 that is housed in each housing unit 3e. Consequently, for example, in the original state in which the wafer 100 is held in the wafer holder 3, even if the whole circumference of the outer edge 100c of the wafer 100 is separated from the face 3e3, the centrifugal force causes the wafer 100 to move toward the outside in the radial direction of the rotation center Ax and makes contact with a contact face 3e6 (a contact making portion, a face) of the wafer holder 3 as illustrated in FIG. 5. In FIG. 5, it is illustrated that the wafer 100 in a warped state is making contact with the contact face 3e6. However, alternatively, the wafer 100 in a non-warped state may also make contact with the contact face 3e6. Herein, the contact face 3e6 includes some portion of the face 3e3. More particularly, of the face 3e3, the portion included in the contact face 3e6 represents the portion positioned on the outside in the radial direction of the rotation center Ax and represents, for example, the portion positioned on the outside in the radial direction of the rotation center Ax as compared to a center of gravity C (the center of the cylindrical housing unit 3e, see FIG. 3) of the wafer 100 that is held. The contact face 3e6 includes the portion of the face 3e3 which is farthest from the rotation center Ax. Moreover, as an example, some portion of the contact face 3e6 protrudes from the face 3b. As illustrated in FIGS. 5 and 6, the face 3e3 has a depression 3e7 (a heat-transfer suppressing portion) that is concave toward the lateral face 3c. Herein, the depression 3e7 is formed on the lower side of the contact face 3e6.

Meanwhile, in the first embodiment, the wafer holder 3 is configured by joining a single member 31 (a first-type member) and members 32 (second-type members, see FIG. 3) disposed corresponding to the supporting members 3e4. The member 31 includes the face 3a, the face 3b, the lateral face 3c, the joining portion 3d, and some portion of the supporting members 3e4. The supporting members 3e4 included in the member 31 include the bottom face 3e2 and the portion of the faces 3e3 other than the contact faces 3e6. Each member 32 includes the contact face 3e6. Moreover, each member 32 is positioned in such a way that, when the wafer holder 3 rotates around the rotation center Ax (the shaft 4), the wafer 100 housed in the corresponding housing unit 3e and subjected to the centrifugal force makes contact with the concerned member 32. Meanwhile, each member 32 may be disposed along the whole circumference of the corresponding housing unit 3e (the corresponding face 3e3).

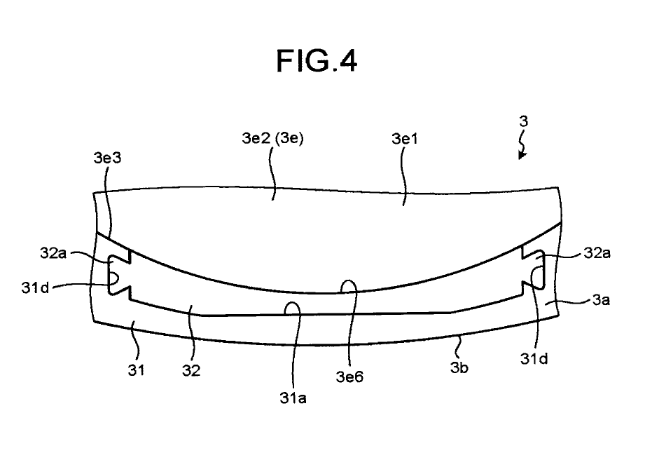

As illustrated in FIGS. 4 to 6, the member 31 has a plurality of joining portions 31a formed thereon. The Mining portions 31a are positioned on the outside of the depressions 3e1 in the radial direction of the rotation center Ax. Each joining portion 31a is joined to the member 32, has a bottom face 31b and has a face 31c (a first-type face) that extends in the upward direction from the bottom face 31b. Herein, the face 31c extends along the circumferential direction of the rotation center Ax. At both ends of the face 31c in the circumferential direction of the rotation center Ax, fitting members 31d are disposed (see FIG. 4).

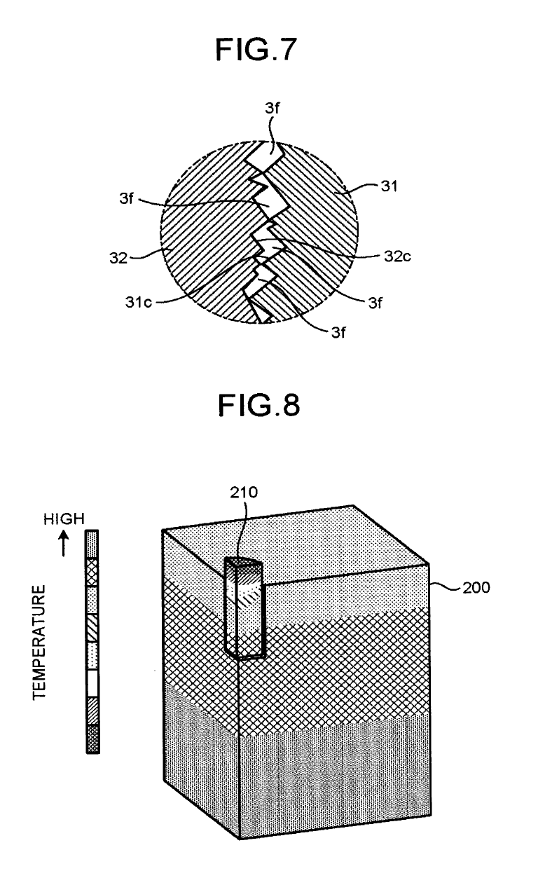

Each member 32 includes a pair of fitting members 32a (see FIG. 4) that are fit with the fitting members 31d. Herein, the fitting between the fitting members 31d and the fitting members 32a is done using a dovetail joint structure. However, the fitting between the fitting members 31d and the fitting members 32a is not limited to a dovetail joint structure. Alternatively, the fitting between the fitting members 31d and the fitting members 32a may be the fitting of straight-shaped members without any dovetail joint. Meanwhile, as illustrated in FIG. 6, each member 32 includes the contact face 3e6 and includes faces 32b and 32c. The face 32b is positioned on the upper side of the bottom face 31b, and is facing the bottom face 31b from some distance. The face 32c (a second-type face) is facing the face 31c and is making contact with the face 31c. The faces 32c and 31c have minute unevenness proportionate to the surface roughness. Due to the unevenness, as illustrated in FIG. 7, gaps 3f (heat-transfer suppressing portion, spaces) are formed between each face 32c (the member 32) and the face 31c (the member 31). Thus, the gaps 3f are formed inside the wafer holder 3. Meanwhile, some part of each member 32 protrudes in the upward direction from the member 31.

Meanwhile, the member 31 is made of a different material than the material of the members 32. The material of the members 32 has a lower thermal conductivity than the thermal conductivity of the material of the member 31. For example, the member 31 is made of carbon, while the members 32 are made of quartz. As another example, the member 31 may be made of silicon carbide or may be manufactured by having a coat of silicon carbide on the surface of a base material made of carbon. The members 32 represent an example of the portion having a low thermal conductivity than the other portion (the member 31), and represent an example of the portion having a different material than the other portion (the member 31). Meanwhile, the materials of the member 31 and the members 32 are not limited to the materials given above.

In the wafer holder 3 having the configuration explained above, the face 3a (a heat receiving portion) receives the heat emitted by the heater 6 (a heat source). Then, the heat received by the face 3a is transferred to the bottom face 3e2. Using the heat received by the face 3a, the bottom face 3e2 (a heating portion) heats each wafer 100. More specifically, the heat released from the bottom face 3e2 is transferred to the face 100b of each wafer 100 via the inside of the depression 3e1. At that time, the heat received by the face 3a is transferred also to the portion of the wafer holder 3 other than the bottom face 3e2. In the first embodiment, in order to curb the transfer of heat to each wafer 100 from the contact face 3e6 which is making contact with the outer edge 100c of the concerned wafer 100; the depression 3e7 (see FIGS. 5 and 6), the member 32 (see FIGS. 3 to 6), and the gaps 3f (see FIG. 7) are provided as the heat-transfer suppressing portion. The depression 3e7 and the member 32 are positioned in between the face 3a and the contact face 3e6 and in between the bottom face 3e2 and the contact face 3e6. The gaps 3f are positioned in between the bottom face 3e2 and the contact face 3e6. Moreover, the member 32 includes the contact face 3e6. In other words, the contact face 3e6 includes the heat-transfer suppressing portion (the member 32) provided thereon. The depression 3e7 and the member 32 are disposed in between the portion of the face 3a positioned immediately below the contact face 3e6 and the contact face 3e6, that is, disposed in the shortest path joining the face 3a and the contact face 3e6. Because of the depression 3e7 and the gaps 3f, the cross-sectional surface of the heat transfer path in the wafer holder 3 becomes locally small, thereby holding down the heat transfer. Moreover, since each member 32 has a lower thermal conductivity than the member 31, the heat transfer is held down. As a result of holding down the heat transfer in this manner, in the first embodiment, the temperature of the contact face 3e6 can become identical to the temperature of the wafer 100.

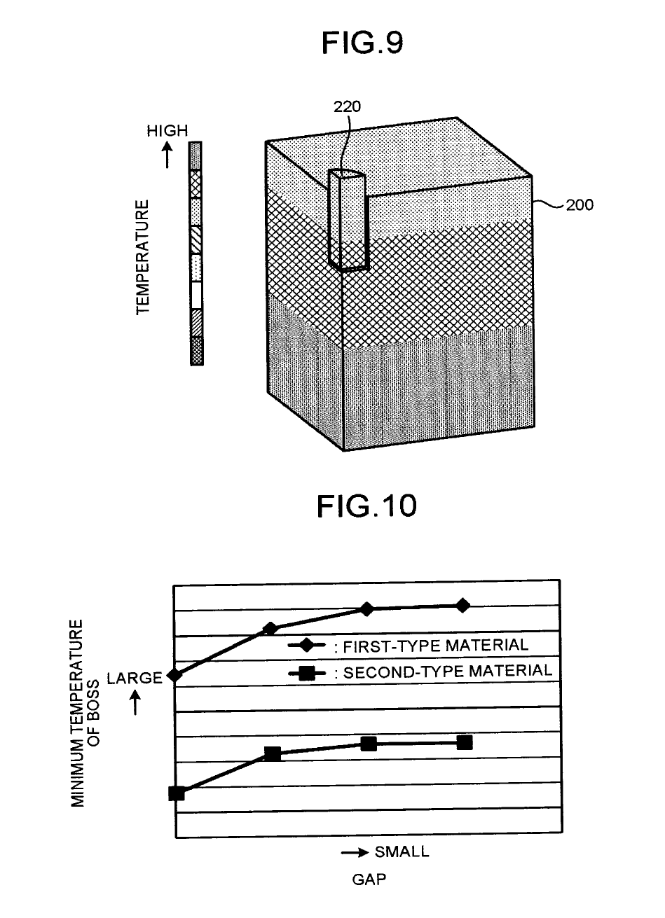

Explained below with reference to FIGS. 8 to 10 is a simulation related to the inter-member heat transfer. Herein, a computer simulation is illustrated about the heat-transfer performance from a member 200, which is made of a first-type material, to a boss 210 (member), which is made of a second-type material (see FIG. 8); and a computer simulation is illustrated about the heat-transfer performance from the member 200, which is made of a first-type material, to a boss 220, which is also made of the first-type material (see FIG. 9). Herein, the second-type material has a lower thermal conductivity than the thermal conductivity of the first-type material. As an example, the first-type material represents carbon, and the second-type material represents quartz. The member 200 has an oblong shape, while the bosses 210 and 220 have the same cylindrical shape. In FIGS. 8 and 9, only some portion (one-fourth) of the member 200 and the bosses 210 and 220 is illustrated. The boss 210 as well as the boss 220 is inserted in a depression formed in the central part of the member 200, and the leading end of the boss 210 as well as the leading end of the boss 220 protrudes from the member 200. When the lower surface of the member 200 was heated, it was observed that the temperature at the upper end of the boss 210 fell below the temperature at the upper end of the boss 220. That is, it was observed that the heat transfer coefficient between the member 200 and the boss 210 is lower than the heat transfer coefficient between the member 200 and the boss 220. Moreover, in this simulation, it was also observed that, greater the gap (the space, the distance) from the member 200 to the boss 210 as well as the boss 220, lower becomes the temperature at the upper end of the boss 220 (see FIG. 10). Thus, the simulation was performed by modeling a phenomenon that, greater the gap (the space, the distance) from the member 200 to the boss 210 as well as the boss 220, smaller becomes the heat transfer coefficient between the member 200 and the boss 210 as well as the boss 220. As a result, it was observed that, greater the gap (the space, the distance) from the member 200 to the boss 210 as well as the boss 220, lower becomes the temperature at the leading end of the boss 210 as well as the boss 220. From the result of this simulation, it is understood that the heat transfer from the member 31, which is made of carbon as an example, to each member 32, which is made of quartz as an example, is held down due to the member 32. Moreover, it is understood that the heat transfer from the member 31 to each member 32 is held down due to the depression 3e7 and the gaps 3f. Furthermore, it is understood that, if the distance between the bottom face 31b of the member 31 and the face 32b of each member 32 is varied, it becomes possible to vary the amount of heat transferred from the bottom face 31b to the face 32b.

Given below is the explanation of the operations (a deposition method, a film formation method, and a wafer processing method) performed by the deposition apparatus 1. In the deposition apparatus 1, a film is formed on the face 100a by means of vapor deposition (chemical vapor deposition). More particularly, in the deposition apparatus 1, while the wafer holder 3 is rotated with the wafers 100 housed in the depressions 3e1, the wafers 100 are heated via the wafer holder 3 by the heat released from the heater 6. Moreover, in the deposition apparatus 1, a gas is supplied from the gas supplying unit 5 into the chamber 2d. Then, the gas supplied into the chamber 2d reacts on the face 100a of each wafer 100 thereby resulting in the formation (deposition) of a film (not illustrated) on the face 100a. The gas that does not get transformed into the film is discharged from the exhaust passage 2f. During these operations, since each wafer 100 rotates around the rotation center Ax, the gas flows along the face 100a so that uniform formation of the film on the face 100a is achieved with ease. In the deposition apparatus 1, as a result of forming a film in a repeated manner, a plurality of films can be laminated on the face 100a. In that case, in the deposition apparatus 1, it is possible to have different gases serving as the raw materials for forming different films. Meanwhile, depending on the difference in the linear coefficient of expansion of the films and the linear coefficient of expansion of the wafer 100 or depending on the difference in the linear coefficients of expansion among the films, there are times when the wafers 100 get warped (see FIG. 5).

As described above, in the first embodiment, in the wafer holder 3, the depression 3e7, the member 32, and the gaps 3f that serve as heat-transfer suppressing portions are provided at least either for the contact face 3e6, or in between the face 3a (a heat receiving portion) and the contact face 3e6, or in between the heater 6 (a heat source) and the contact face 3e6 for the purpose of holding down the heat transfer. As a result, it becomes possible to hold the transfer of heat from the face 3a and the bottom face 3e2 to the wafer 100 via the contact face 3e6. Hence, in each wafer 100, the temperature of the portion making contact with the contact face 3e6 can be prevented from rising locally, thereby making it possible to hold down the variability in the temperature distribution of the wafer 100.

In the first embodiment, due to the centrifugal force, each wafer 100 is pressed against the contact face 3e6. Moreover, because of the centrifugal force, each wafer 100 may undergo deformation in such a way that the contact area between the contact face 3e6 and the wafer 100 increases, or there may be an increase in the degree of adhesion between the contact face 3e6 and the wafer 100. Consequently, there occurs an increase in the contact area between the wafer 100 and the contact face 3e6. However, in the first embodiment, the transfer of heat from the contact face 3e6 to the wafer 100 can be held down as described above. Therefore, even if there is an increase in the contact area between the wafer 100 and the contact face 3e6 due to the centrifugal force, it becomes possible to hold down the variability in the temperature distribution of the wafer 100. Meanwhile, the supporting members 3e4 are also making contact with the wafer 100. However, since the contact area between the supporting members 3e4 and the wafer 100 is smaller as compared to the contact area between the contact face 3e6 and the wafer 100, there is comparatively less transfer of heat from the supporting members 3e4 to the wafer 100. For that reason, the effect of the contact between the supporting members 3e4 and the wafer 100 on the temperature distribution of the wafer 100 is small enough to be ignorable. Moreover, since the centrifugal force does not cause pressing of the wafer 100 against the supporting members 3e4, the contact area between the supporting members 3e4 and the wafer 100 is less likely to increase. Even so, heat-transfer suppressing portions may be provided corresponding to the supporting members 3e4 too.

Moreover, in the first embodiment, the bottom face 3e2 is positioned separated from the wafer 100 in the thickness direction of the wafer 100. Since the bottom face 3e2 is separated from the wafer 100, it becomes possible to hold down excessive transfer of heat to the wafer 100 as compared to a configuration in which the bottom face 3e2 is wholly making contact with the wafer 100. Furthermore, in a configuration in which the bottom face 3e2 is wholly making contact with the wafer 100, if the wafer 100 gets warped, then the bottom face 3e2 and the face 100a of the wafer 100 become partially separated from each other. That leads to variability in the transfer of heat from the bottom face 3e2 to the wafer 100. In contrast, in the first embodiment, the bottom face 3e2 is positioned separated from the wafer 100 in the thickness direction of the wafer 100. Therefore, it becomes possible to prevent variability in the transfer of heat to the face 100a of the wafer 100.

Moreover, the depression 3e7 and the member 32 are disposed in the shortest route joining the face 3a and the contact face 3e6. As a result, it becomes possible to hold down the transfer of heat from the face 3a to the contact face 3e6.

Meanwhile, in the first embodiment, the explanation is given for an example in which the member 31 and the members 32 are made of mutually different materials. However, alternatively, the member 31 and the members 32 may be made of the same material. As long as the member 31 and the members 32 are made of a material such as carbon, silicon carbide, or quartz; it serves the purpose. In such a configuration too, because of the depression 3e7 and the gaps 3f, it becomes possible to hold down the transfer of heat from the face 3a and the bottom face 3e2 to the wafer 100 via the contact face 3e6. Therefore, in each wafer 100, the temperature of the portion making contact with the contact face 3e6 can be prevented from rising locally, thereby making it possible to hold down the variability in the temperature distribution of the wafer 100.

### FIRST MODIFICATION EXAMPLE

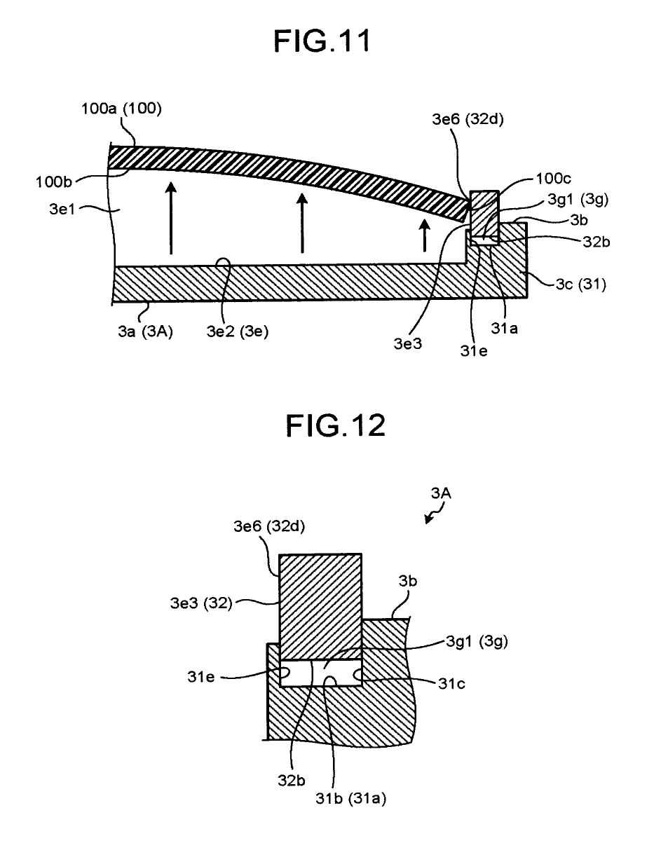

As illustrated in FIGS. 11 and 12, a wafer holder 3A according to a first modification example differs from the first embodiment in the way that each joining portion 31a of the member 31 (a first-type member) of the wafer holder 3 has a face 31e in addition to having the bottom face 31b and the face 31c. In each joining portion 31a, the portion including the bottom face 31b, the face 31c, and the face 31e leads to the formation of a depression 3g. In some portion of each depression 3g, one of the members 32 (a second-type member) is inserted. The face 31e is disposed opposite to the face 31c, and is making contact with the contact face 3e6 of the member 32. In between the face 31e (a first-type face) and the contact face (a second-type face), the gaps 3f are formed (see FIG. 7) in an identical manner to the gaps 3f formed in between the face 32c and the face 31c. Moreover, the member 32 covers the depression 3g in such a way that a space 3g1 (a heat-transfer suppressing portion) is formed. The space 3g1 is formed in between the bottom face 31b and the face 32b.

In such a configuration, because of the gaps 3f and the space 3g1, the transfer of heat from the face 3a and the bottom face 3e2 to the contact face 3e6 is held down. That makes it possible to hold down the transfer of heat from the contact face 3e6 to the wafer 100. Consequently, in each wafer 100, the temperature of the portion making contact with the contact face 3e6 can be prevented from rising locally, thereby making it possible to hold down the variability in the temperature distribution of the wafer 100.

### SECOND MODIFICATION EXAMPLE

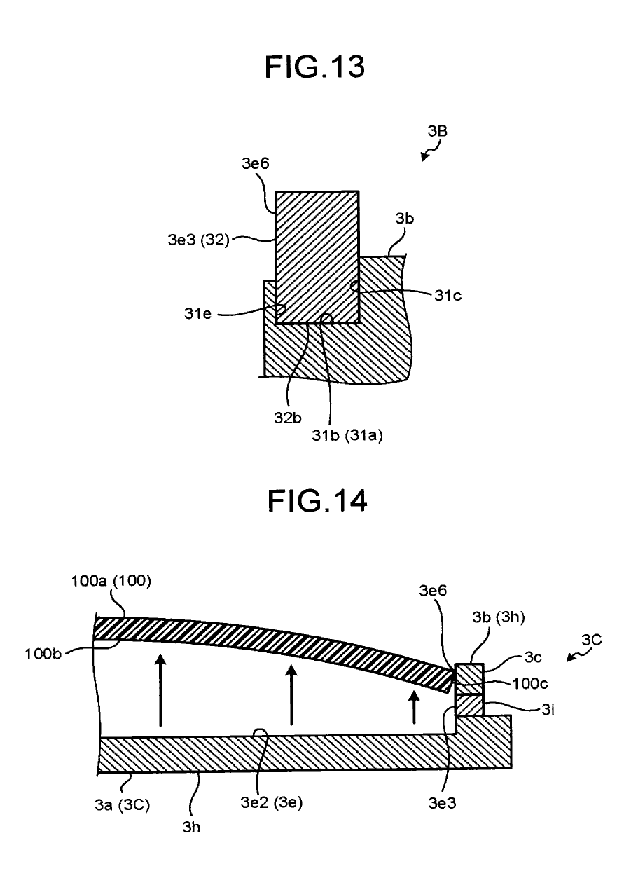

As illustrated in FIG. 13, a wafer holder 38 according to the second modification example differs from the first modification example in the way that the bottom face 31b and the face 32b are in contact with each other. As a result, in between the bottom face 31b (a first-type face) and the face 32b (a second-type face), the gaps 3f are formed (see FIG. 7). In such a configuration, because of the gaps 3f, the transfer of heat from the face 3a and the bottom face 3e2 to the contact face 3e6 is held down. That makes it possible to hold down the transfer of heat from the contact face 3e6 to the wafer 100. Consequently, in each wafer 100, the temperature of the portion making contact with the contact face 3e6 can be prevented from rising locally, thereby making it possible to hold down the variability in the temperature distribution of the wafer 100.

### Second Embodiment

In a second embodiment, as illustrated in FIG. 14, the configuration of a wafer holder 3C mainly differs from the first embodiment. The wafer holder 3C includes a first-type material portion 3h (a portion) and a second-type material portion 3i (portion) having different materials, and is configured as a single molded member. The wafer holder 3C can be manufactured using, for example, a 3D printer (a laminating and shaping apparatus).

The first-type material portion 3h includes the face 3a, the face 3b, the bottom face 3e2, and the contact face 3e6. The second-type material portion 31 includes some part of the face 3e3. Moreover, the second-type material portion 3i is sandwiched between the first-type material portion 3h in the vertical direction.

The second-type material portion 3i is made of a material having a lower thermal conductivity than the material of the first-type material portion 3h. That is, the second-type material portion 3i has a lower thermal conductivity than the first-type material portion 3h. For example, the first-type material portion 3h is made of carbon, while the second-type material portion 3i is made of quartz. Herein, the second-type material portion 3i represents an example of the portion having a lower thermal conductivity than the other portion (the first-type material portion 3h), as well as represents an example of the portion made of a different material than the other portion (the first-type material portion 3h). Moreover, at least some portion of the second-type material portion 3i is positioned in the space ranging from the face 3a and the bottom face 3e2 up to the contact face 3e6.

In such a configuration, because of the second-type material portion 3i, the transfer of heat from the face 3a and the bottom face 3e2 to the contact face 3e6 is held down. That makes it possible to hold down the transfer of heat from the contact face 3e6 to the wafer 100. Consequently, in each wafer 100, the temperature of the portion making contact with the contact face 3e6 can be prevented from rising locally, thereby making it possible to hold down the variability in the temperature distribution of the wafer 100.

### Third Embodiment

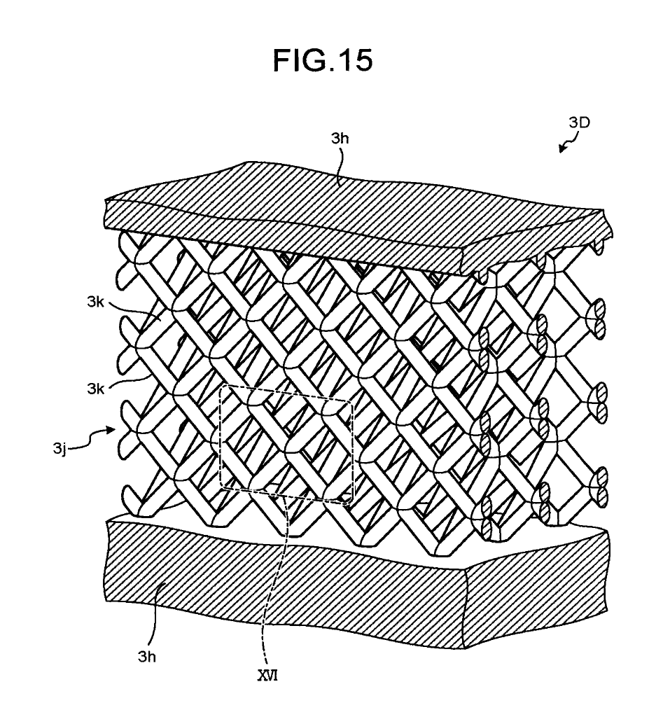

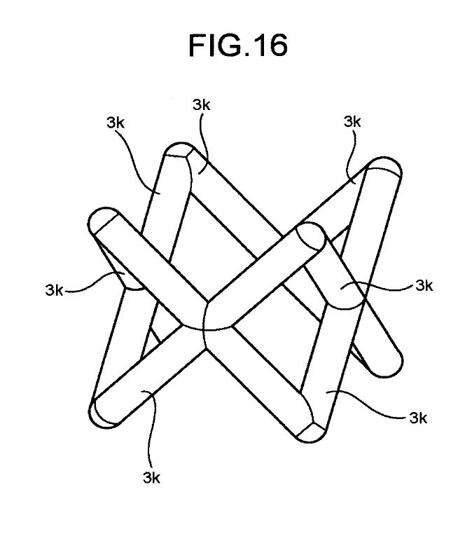

In a third embodiment, as illustrated in FIGS. 15 and 16, a wafer holder 3D differs from the second embodiment mainly in the way that a grid-like structure 3j is disposed. Herein, the grid-like structure 3j (a heat-transfer suppressing portion) is configured by arranging a plurality of columnar members 3k in a three-dimensional grid pattern. Thus, the grid-like structure 3j includes a plurality of columnar members 3k spaced apart from each other. As an example, the grid-like structure 3j is disposed in place of the second-type material portion 3i according to the second embodiment. Meanwhile, the grid-like structure 3j either may be formed in an integrated manner with the other portion of the wafer holder 3D, or may be formed as a separate member. Moreover, the grid-like structure 3j is made of a different material (such as quartz) than the material of the first-type material portion 3h. However, alternatively, the grid-like structure 3j may be made of the same material as the first-type material portion 3h.

In such a configuration, because of the grid-like structure 3j, the transfer of heat from the face 3a and the bottom face 3e2 to the contact face 3e6 is held down. That makes it possible to hold down the transfer of heat from the contact face 3e6 to the wafer 100. Consequently, in each wafer 100, the temperature of the portion making contact with the contact face 3e6 can be prevented from rising locally, thereby making it possible to hold down the variability in the temperature distribution of the wafer 100.

### Fourth Embodiment

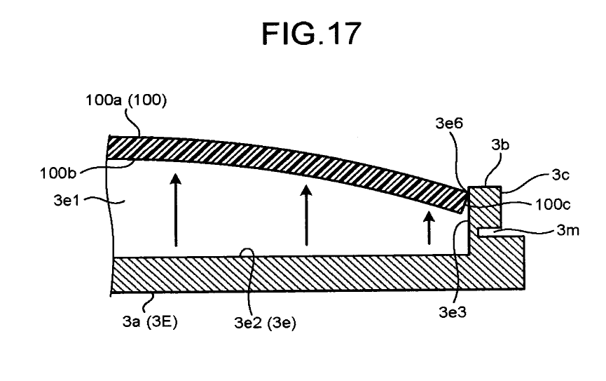

In a fourth embodiment, as illustrated in FIG. 17, a wafer holder 3E differs from the first embodiment mainly in the way that a depression 3m (a heat-transfer suppressing portion) is formed on the lateral face 3c. The depression 3m is formed in between the face 3a and the contact face 3e6. In such a configuration, because of the depression 3m, the transfer of heat from at least the face 3a to the contact face 3e6 is held down. That makes it possible to hold down the transfer of heat from the contact face 3e6 to the wafer 100. Consequently, in each wafer 100, the temperature of the portion making contact with the contact face 3e6 can be prevented from rising locally, thereby making it possible to hold down the variability in the temperature distribution of the wafer 100.

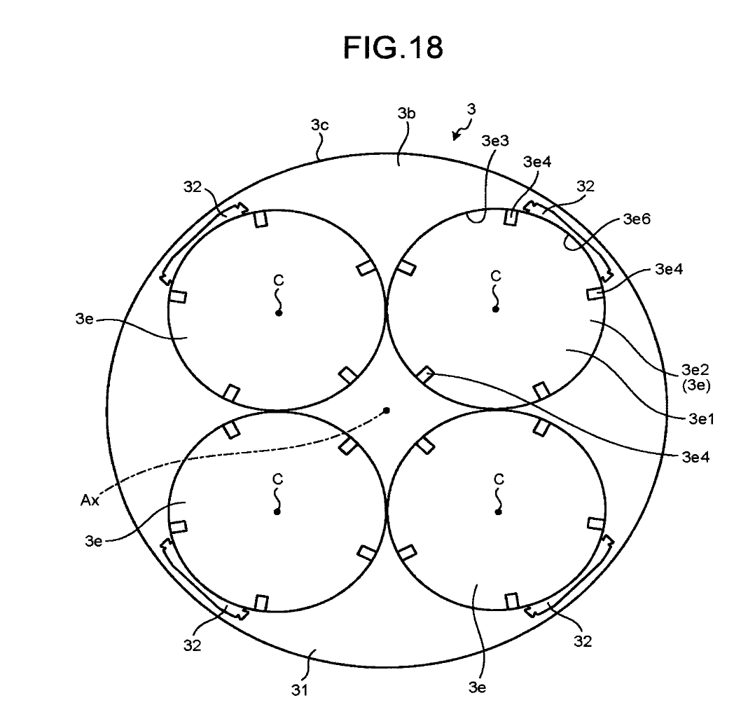

Herein, although the invention is described with reference to the abovementioned embodiments for a complete and clear disclosure, the appended claims are not to be thus limited but are to be construed as embodying all modifications and alternative constructions that may occur to one skilled in the art that fairly fall within the basic teaching herein set forth. Moreover, the specifications regarding the configuration, the shape, and the display elements (structure, type, direction, shape, size, length, width, thickness, height, number, arrangement, position, material, etc.) can be suitably modified. Meanwhile, the heat-transfer suppressing portion may represent, for example, a parallel arrangement of a plurality of columnar members. Alternatively, the heat-transfer suppressing portion may be configured in a porous manner. Still alternatively, the heat-transfer suppressing portion may be configured in a reticulated manner. Meanwhile, the number of housing units 3e in the wafer holder 3 is not limited to three as illustrated in FIG. 3. Alternatively, there may be one or two housing units 3e, or there may be four or more housing units 3e. In FIG. 18 is illustrated a configuration in which four housing units 3e are disposed in the wafer holder 3 (another embodiment). Still alternatively, the housing units 3e may be arranged in such a way that the centers thereof are substantially coincident with the rotation center Ax. In that case, for example, each member 32 can be arranged in a circular pattern along the whole circumference of the corresponding housing unit 3e (the face 3e3). As a result, each wafer 100 that is subjected to centrifugal force can make contact at some portion of the member 32.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A wafer holder comprising:
a heat receiving portion that receives heat from a heat source;
a heating portion that heats a wafer using the heat received by the heat receiving portion; and
a contact making portion that makes contact with an outer edge of the wafer, wherein
a heat-transfer suppressing portion is provided at least either for the contact making portion, or in between the heat receiving portion and the contact making portion, or in between the heating portion and the contact making portion.

2. The wafer holder according to claim 1, wherein the heat-transfer suppressing portion represents a portion having a lower thermal conductivity than other portion.

3. The wafer holder according to claim 1, wherein the heat-transfer suppressing portion represents a space formed inside the wafer holder.

4. The wafer holder according to claim 3, further comprising:
a first-type member having a first-type face; and
a second-type member having a second-type face that makes contact with the first-type face, wherein
the space represents a gap formed in between the first-type face and the second-type face.

5. The wafer holder according to claim 1, wherein the heat-transfer suppressing portion represents a portion made of a different material than other portion.

6. The wafer holder according to claim 1, wherein the heat-transfer suppressing portion represents a depression formed in the wafer holder.

7. The wafer holder according to claim 1, wherein the heat-transfer suppressing portion represents a plurality of columnar members spaced apart from each other.

8. The wafer holder according to claim 7, wherein the plurality of columnar members are arranged in a grid pattern.

9. The wafer holder according to claim 1, wherein
the wafer holder is configured in a rotatable manner around a rotation center, and
the heat-transfer suppressing portion is provided corresponding to the contact making portion that is positioned on outside in radial direction of the rotation center with respect to center of gravity of the wafer.

10. A deposition apparatus comprising:
a container;
the wafer holder according to claim 1 and holding a wafer inside the container;
the heat source; and
a gas supplying unit that supplies a gas inside the container.
